(19) United States
(12) Patent Application Publication
(10) Pub. No.: US 2025/0159845 A1
(43) Pub. Date: May 15, 2025

(54) COMBINED REFRIGERATION SYSTEM FOR HIGH-DENSITY DATA CENTER BASED ON AIR-COOLED AIR CONDITIONER AND LIQUID COOLING

(71) Applicant: Hebei Qinhuai Data Co., Limited., Zhangjiakou City (CN)

(72) Inventor: Binghua ZHANG, Zhangjiakou City (CN)

(21) Appl. No.: 18/937,435

(22) Filed: Nov. 5, 2024

(30) Foreign Application Priority Data
Nov. 14, 2023 (CN) 202311515476.4

(51) Int. Cl. H05K 7/20

(52) U.S. Cl. CPC H05K 7/20772; H05K 7/20263; H05K 7/2079

(57) ABSTRACT

The present disclosure discloses a combined refrigeration system for a high-density data center based on an air-cooled air conditioner and a liquid cooling radiator, to solve a problem that a single refrigeration technology used in the high-density data center is difficult to adapt to rapidly increasing heat dissipation capacity. This system is equipped with a plurality of server cabinets in a server room of the data center, and each server is equipped with a liquid cooling radiator directly connected to a CPU/GPU chip to transmit heat from the CPU/GPU chip. Furthermore, one or more air-cooled air conditioners are arranged in the server room to transmit heat from other components of servers and other devices in the server room. Moreover, there is also equipped with an enclosed hot aisle to isolate hot and cold air inside the server cabinets. Capacity of the air-cooled air conditioner and of the liquid cooling radiator may be selected and configured according to actual layout of the data center. By means of collaborative operation between the air-cooled air conditioner and the liquid cooling radiator and introduction of an intelligent monitoring and control system, comprehensive refrigeration of the high-density data center is achieved, and refrigeration efficiency and energy conservation level are improved.

### CROSS REFERENCE TO RELATED APPLICATION

This application claims priority to Chinese Patent Application No. 202311515476.4, titled “COMBINED REFRIGERATION SYSTEM FOR HIGH-DENSITY DATA CENTER BASED ON AIR-COOLED AIR CONDITIONER AND LIQUID COOLING RADIATOR” and filed to the China National Intellectual Property Administration on Nov. 14, 2023, the entire contents of which are incorporated herein by reference.

### TECHNICAL FIELD

The present disclosure relates to the technical field of a refrigeration system for a high-density data center, and more particularly, to a combined refrigeration system for the high-density data center based on an air-cooled air conditioner and a liquid cooling radiator.

### BACKGROUND

With the rapid development of emerging information technologies such as cloud computing, big data, and artificial intelligence, scales of data centers continue to expand, servers and storage devices are highly concentrated, computing power density, transmission bandwidth, and heat load of the data centers are grow exponentially. According to statistics, power density of one typical data center generally ranges from 1 kilowatt per square meter to 20 kilowatts per square meter, and the power density of a high-density data center may even reach 20 to 40 kilowatts per square meter. Meanwhile, heat dissipation of information devices mainly relies on traditional air-cooled air conditioning systems. However, with the continuous increase in heat dissipation density of the data centers, relying solely on the air-cooled air conditioning systems becomes hard to satisfy refrigeration needs.

At present, data center refrigeration technologies mainly include air cooling technologies and liquid cooling technologies. The air cooling technologies are widely used. Outdoor air is mixed, filtered, humidified, and refrigerated before entering data rooms, to remove heat from devices in the data rooms. However, when the power density and the heat load of the data centers continue to increase, it becomes difficult to achieve effective refrigeration relying solely on the air-cooled air conditioning systems. The liquid cooling technologies remove the heat through phase change of liquids, theoretically resulting in higher refrigeration efficiency. However, when the liquid cooling technologies are used solely, it is unable to remove a large amount of heat generated by other auxiliary devices in the data centers.

Therefore, how to achieve efficient thermal management in high-density data centers is a technical problem that urgently needs to be solved at present.

### SUMMARY

To solve problems in existing technologies, embodiments of the present disclosure provide a combined refrigeration system for a high-density data center based on an air-cooled air conditioner and a liquid cooling radiator. The technical solutions are described as follows.

In one aspect, there is provided a combined refrigeration system for a high-density data center based on an air-cooled air conditioner and a liquid cooling radiator, including:
at least one server cabinet, where each of the at least one server cabinet is equipped with at least one server, each of the at least one server is equipped with at least one liquid cooling radiator internally provided with a liquid cooling unit, and the liquid cooling unit is connected to a CPU/GPU chip of the server and is configured to transmit heat generated by the CPU/GPU chip to an outdoor cooling device through a liquid;
at least one air-cooled air conditioner, where each of the at least one air-cooled air conditioner is communicated with at least one hot aisle and is configured to discharge heat generated by another heat dissipation device except for the CPU/GPU chip in the server cabinet and a power distribution cable and an electric device in a server room by means of air circulation; and
at least one enclosed hot aisle, where each of the at least one enclosed hot aisle is corresponding to at least one server cabinet and is configured to isolate hot air inside the server cabinet from cold air inside the server room, to form a separate hot aisle.

Further, as a large air-cooled air conditioner, the air-cooled air conditioner is arranged inside or outside the server room, and is communicated with the server cabinet through an air duct.

Further, the large air-cooled air conditioner is a variable frequency air-cooled air conditioner, and is configured to automatically adjust refrigeration capacity and air quantity according to temperature and humidity inside the server room.

Further, as a small air-cooled air conditioner, the air-cooled air conditioner is arranged at a top or bottom of the server cabinet, and is directly communicated with the hot aisle inside the server cabinet.

Further, the small air-cooled air conditioner is an air-cooled air conditioner having a modular functionality and is configured to automatically adjust refrigeration capacity and air quantity according to temperature and humidity inside the server cabinet, to achieve linkage control between a plurality of small air-cooled air conditioners.

Further, the outdoor cooling device is one of a dry cooling tower, a wet cooling tower, a plate heat exchanger, a heat pipe exchanger, or another device capable of cooling the liquid.

Further, the liquid cooling unit is either a direct-contact liquid cooling unit or an indirect-contact liquid cooling unit, and is configured to tightly adhere the liquid to a surface or rear face of the CPU/GPU chip, to achieve efficient heat conduction.

Further, the enclosed hot aisle is one of a curtain board made of a soft material, a curtain board made of a hard material, a door, a window, or a structure configured to isolate air flow.

The technical solutions provided by the embodiments of the present disclosure achieve the following beneficial effects.

Comprehensive refrigeration of the high-density data center is achieved, refrigeration efficiency and energy conservation and emission reduction indicators are taken into account, and it is solved the problem that a single refrigeration technology is difficult to adapt to changes in requirements for heat dissipation of the data center.

By combining the air-cooled air conditioner with the liquid cooling radiator, refrigeration responsibilities of different areas are reasonably divided, respective advantages of the two cooling technologies are utilized, and thus overall efficiency of the refrigeration system is improved.

By adopting modular and intelligent control modes, different models and specifications of air-cooled air conditioners and liquid cooling radiators may be flexibly adjusted according to actual situations of the data center, to achieve precise control of environmental parameters of the server room.

The enclosed hot aisle is arranged to isolate cold air and hot air inside the cabinet, to avoid mixing of the cold air and the hot air, thereby reducing energy consumption of the refrigeration system.

Introduction of a monitoring system may adjust operating parameters of each refrigeration unit in real time based on sensor data, thereby ensuring efficient, economic, and safe operation of the system.

Based on the technical solutions, acceptable refrigeration solutions can be designed according to layout and structural requirements of different data centers.

### BRIEF DESCRIPTION OF THE DRAWINGS

To describe the technical solutions in the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic modular diagram of a combined refrigeration system for a high-density data center based on an air-cooled air conditioner and a liquid cooling radiator according to Embodiment 1 of the present disclosure; and

FIG. 2 is a schematic modular diagram of a combined refrigeration system for a high-density data center based on an air-cooled air conditioner and a liquid cooling radiator according to Embodiment 2 of the present disclosure.

### DETAILED DESCRIPTION

To make the objectives, technical solutions and advantages of the present disclosure clearer, the embodiments of the present disclosure will be further described as below in details with reference to the accompanying drawings.

The present disclosure provides a combined refrigeration system for a high-density data center based on an air-cooled air conditioner and a liquid cooling radiator, which can effectively solve the refrigeration problem for the high-density data center through the combination of the air-cooled air conditioner with the liquid cooling radiator.

### Embodiment 1

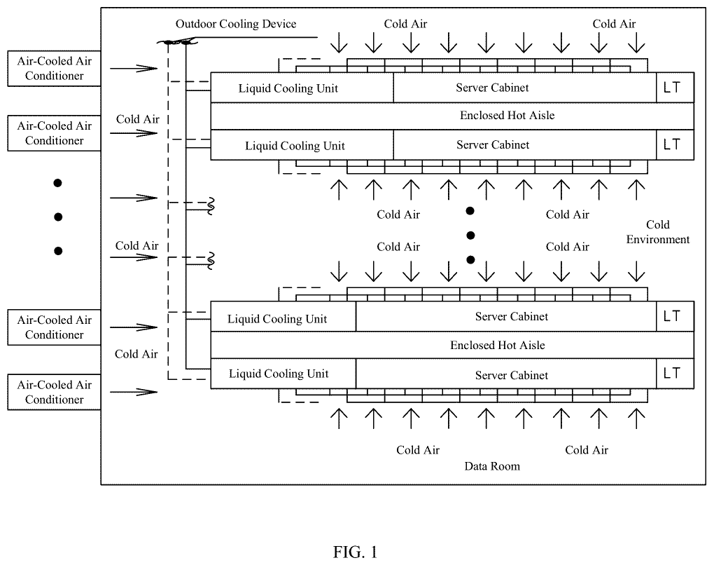

As a large air-cooled air conditioner, the air-cooled air conditioner used in this embodiment is arranged inside or outside a server room and is communicated with a server cabinet through an air duct. As a variable frequency air-cooled air conditioner, the air-cooled air conditioner is configured to automatically adjust refrigeration capacity and air quantity according to temperature and humidity inside the server room. A specific structure of the large air-cooled air conditioner in this embodiment is shown in FIG. 1.

The air-cooled air conditioner in this embodiment includes:
a server cabinet internally provided with a plurality of servers, where each of the plurality of servers is equipped with a liquid cooling radiator internally provided with a liquid cooling unit, and the liquid cooling unit is connected to a CPU/GPU chip of the server and is configured to transmit heat generated by the CPU/GPU chip to an outdoor cooling device through a liquid;
a large air-cooled air conditioner arranged inside or outside the server room and communicated with the server cabinet through an air duct, where the large air-cooled air conditioner is configured to discharge heat generated by another heat dissipation device except for the CPU/GPU chip in the server cabinet and a power distribution cable and an electric device in the server room by means of air circulation; and
an enclosed hot aisle corresponding to the server cabinet, where the enclosed hot aisle is configured to isolate hot air inside the server cabinet from cold air inside the server room, to form a separate hot aisle.

Operating principles of the air-cooled air conditioner in this embodiment are as follows.

When a server is running, the CPU/GPU chip generates a large amount of heat, which is in contact with the liquid by means of the liquid cooling unit and is taken away.

After passing through the liquid cooling radiator, the liquid flows into the outdoor cooling device, in which the liquid is cooled down and then flows back to the liquid cooling unit, thereby forming an enclosed circulation system.

The heat generated by another heat dissipation device except for the CPU/GPU chip in the server cabinet and the power distribution cable and the electric device in the server room is discharged through the large air-cooled air conditioner.

The large air-cooled air conditioner sucks the hot air from the server room through the air duct, cools it down by means of a refrigerant, and then sends out the cold air.

The cold air flows into the enclosed hot aisle inside the server cabinet through the air duct and forms a negative pressure zone therein.

The enclosed hot aisle isolates the hot air inside the server cabinet from the cold air inside the server room, such that the hot air can only flow in from a back of the server and flow out of a front of the server.

Due to effects of the negative pressure zone, the hot air is forced to flow out of the front of the server and is sucked in again by the large air-cooled air conditioner, thereby forming an enclosed circulation system.

As a variable frequency air conditioner, the large air-cooled air conditioner can automatically adjust the refrigeration capacity and the air quantity according to the temperature and humidity inside the server room, to keep the temperature and humidity inside the server room within an appropriate range.

Advantages of the air-cooled air conditioner in this embodiment are as follows.

The combined use of the liquid cooling radiator and the large air-cooled air conditioner can effectively solve the refrigeration problem for the high-density data center and save energy and space.

Arrangement of the enclosed hot aisle can avoid mixing of the hot air and the cold air and can improve refrigeration efficiency and air quality.

By means of the variable frequency large air-cooled air conditioner, refrigeration parameters can be automatically adjusted according to the actual situations of the server room, to improve refrigeration performance and intelligence level.

Specific implementation manners of this embodiment also include following technical features.

The server cabinets are standard 19 inch cabinets, each cabinet can accommodate 42 servers, and each server has a height of 1 U.

As a plate heat exchanger, the liquid cooling radiator uses a heat dissipation module comprised of copper pipes and aluminum sheets. The liquid cooling radiator is closely adhered to the CPU/GPU chip of the server, to form an enclosed liquid circulation system.

As a direct-contact liquid cooling unit, the liquid cooling unit is made of metal materials with good thermal conductivity. The liquid cooling unit is tightly adhered to the surface or rear face of the CPU/GPU chip to achieve efficient heat conduction.

The liquid is a colorless and odorless low-viscosity liquid with good thermal conductivity and low evaporation rate, such as water, ethylene glycol, and propylene glycol, etc.

The outdoor cooling device is a dry cooling tower, and it uses a fan to blow ambient air through cooling tube bundles inside the cooling tower, such that the liquid is cooled down inside the cooling tube bundles.

As a variable frequency air-cooled air conditioner, the large air-cooled air conditioner is a refrigeration cycle system comprised of a compressor, an evaporator, a condenser, an expansion valve and so on, to achieve refrigeration effects through phase change of the refrigerant at different pressures.

As a pipe made of metal or plastic materials, the air duct is used for transporting air between the large air-cooled air conditioner and the server cabinet.

The enclosed hot aisle is a curtain board made of a hard material, and is used for isolating the hot air behind the server cabinet from the cold air inside the server room.

### Embodiment 2

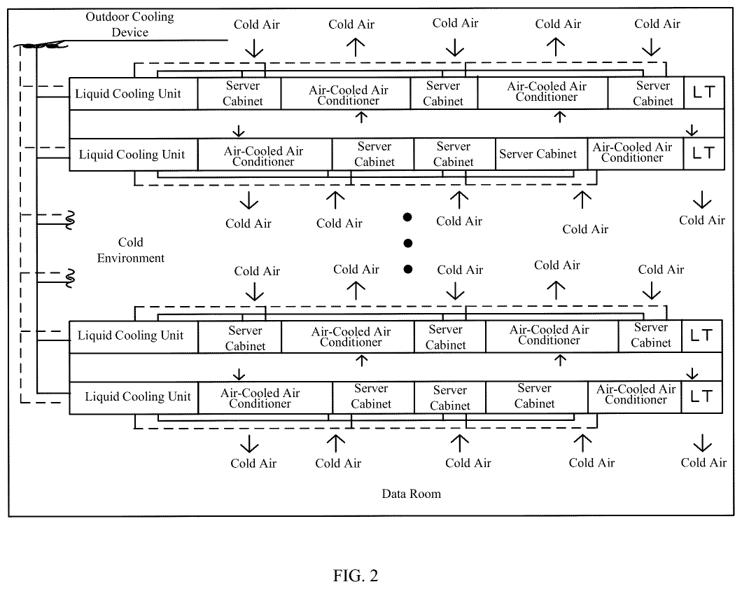

As a small air-cooled air conditioner, the air-cooled air conditioner used in this embodiment is arranged at a top or bottom of the server cabinet and is directly communicated with the hot aisle inside the server cabinet. The small air-cooled air conditioner has modular functionality, and is used for automatically adjusting refrigeration capacity and air quantity according to temperature and humidity inside the server cabinet, to achieve linkage control between a plurality of small air-cooled air conditioners. A specific structure of the small air-cooled air conditioner in this embodiment is shown in FIG. 2.

The air-cooled air conditioner in this embodiment includes:
a server cabinet internally provided with a plurality of servers, where each of the plurality of servers is equipped with a liquid cooling radiator internally provided with a liquid cooling unit, and the liquid cooling unit is connected to a CPU/GPU chip of the server and is configured to transmit heat generated by the CPU/GPU chip to an outdoor cooling device through a liquid;
a small air-cooled air conditioner arranged at the top or bottom of the server room and directly communicated with the hot aisle inside the server cabinet, where the small air-cooled air conditioner is configured to discharge heat generated by another heat dissipation device except for the CPU/GPU chip in the server cabinet and a power distribution cable and an electric device in the server room by means of air circulation; and
an enclosed hot aisle corresponding to the server cabinet, where the enclosed hot aisle is configured to isolate hot air inside the server cabinet from cold air inside the server room, to form a separate hot aisle.

Operating principles of the air-cooled air conditioner in this embodiment are as follows.

When a server is running, the CPU/GPU chip generates a large amount of heat, which is in contact with the liquid by means of the liquid cooling unit and is taken away.

After passing through the liquid cooling radiator, the liquid flows into the outdoor cooling device, in which the liquid is cooled down and then flows back to the liquid cooling unit, thereby forming an enclosed circulation system.

The heat generated by another heat dissipation device except for the CPU/GPU chip in the server cabinet and the power distribution cable and the electric device in the server room is discharged through the small air-cooled air conditioner.

The small air-cooled air conditioner is directly communicated with the hot aisle inside the server cabinet, and sucks the hot air therein, cools it down by means of a refrigerant, and then sends out the cold air.

The cold air flows into the enclosed hot aisle inside the server cabinet through the small air-cooled air conditioner and forms a negative pressure zone therein.

The enclosed hot aisle isolates the hot air inside the server cabinet from the cold air inside the server room, such that the hot air can only flow in from the back of the server and flow out of the front of the server.

Due to the effects of the negative pressure zone, the hot air is forced to flow out of the front of the server and is sucked in again by the small air-cooled air conditioner, thereby forming an enclosed circulation system.

Through the modular functionality of the small air-cooled air conditioner, the refrigeration capacity and the air quantity can be automatically adjusted according to the temperature and humidity inside the server cabinet, and the linkage control between a plurality of small air-cooled air conditioners can be achieved, to improve refrigeration performance and intelligence level.

Advantages of the small air-cooled air conditioner in this embodiment are as follows.

The combined use of the liquid cooling radiator and the small air-cooled air conditioner can effectively solve the refrigeration problem for the high-density data center and save energy and space.

Arrangement of the enclosed hot aisle can avoid mixing of the hot air and the cold air and can improve the refrigeration efficiency and the air quality.

Through the modular functionality of the small air-cooled air conditioner, the refrigeration capacity and the air quantity can be automatically adjusted according to the temperature and humidity inside the server cabinet, and the linkage control between a plurality of small air-cooled air conditioners can be achieved, to improve the refrigeration performance and the intelligence level.

Specific implementation manners of this embodiment also include following technical features.

The server cabinets are standard 19 inch cabinets, each cabinet can accommodate 42 servers, and each server has a height of 1 U.

As a plate heat exchanger, the liquid cooling radiator uses a heat dissipation module comprised of copper pipes and aluminum sheets. The liquid cooling radiator is closely adhered to the CPU/GPU chip of the server, to form an enclosed liquid circulation system.

As an indirect-contact liquid cooling unit, the liquid cooling unit is made of metal materials with good thermal conductivity. The liquid cooling unit is tightly adhered to the rear face of the CPU/GPU chip to achieve efficient heat conduction.

The liquid is a colorless and odorless low-viscosity liquid with good thermal conductivity and low evaporation rate, such as water, ethylene glycol, and propylene glycol, etc.

The outdoor cooling device is a wet cooling tower, and it uses spray water to moisten the ambient air and then blows the moistened air through cooling tube bundles inside the cooling tower, such that the liquid is cooled down inside the cooling tube bundles.

As an air-cooled air conditioner having the modular functionality, the small air-cooled air conditioner is a refrigeration cycle system comprised of a compressor, an evaporator, a condenser, an expansion valve and so on, to achieve the refrigeration effects through phase change of the refrigerant at different pressures.

The small air-cooled air conditioner is directly communicated with the hot aisle inside the server cabinet, and linkage control between the small air-cooled air conditioner and other small air-cooled air conditioners is performed through wireless signals to achieve collaborative operation among the plurality of small air-cooled air conditioners.

The enclosed hot aisle is a curtain board made of a soft material, and is used for isolating the hot air behind the server cabinet from the cold air inside the server room.

The foregoing descriptions are merely preferred embodiments of the present disclosure, and are not intended to limit the present disclosure. Any modification, equivalent replacement and improvement made within the spirit and principle of the present disclosure shall fall into the protection scope of the present disclosure.

What is claimed is:

1. A combined refrigeration system for a high-density data center based on an air-cooled air conditioner and a liquid cooling radiator, comprising:
at least one server cabinet, each of the at least one server cabinet being equipped with at least one server, each of the at least one server being equipped with at least one liquid cooling radiator internally provided with a liquid cooling unit, the liquid cooling unit being connected to a CPU/GPU chip of the server and configured to transmit heat generated by the CPU/GPU chip to an outdoor cooling device through a liquid;
at least one air-cooled air conditioner, each of the at least one air-cooled air conditioner being communicated with at least one hot aisle and configured to discharge heat generated by another heat dissipation device except for the CPU/GPU chip in the server cabinet and a power distribution cable and an electric device in a server room by means of air circulation; and
at least one enclosed hot aisle, each of the at least one enclosed hot aisle being corresponding to at least one server cabinet and being configured to isolate hot air inside the server cabinet from cold air inside the server room, to form a separate hot aisle.

2. The combined refrigeration system according to claim 1, wherein as a large air-cooled air conditioner, the air-cooled air conditioner is arranged inside or outside the server room, and is communicated with the server cabinet through an air duct.

3. The combined refrigeration system according to claim 2, wherein the large air-cooled air conditioner is a variable frequency air-cooled air conditioner, and is configured to automatically adjust refrigeration capacity and air quantity according to temperature and humidity inside the server room.

4. The combined refrigeration system according to claim 1, wherein as a small air-cooled air conditioner, the air-cooled air conditioner is arranged at a top or bottom of the server cabinet, and is directly communicated with the hot aisle inside the server cabinet.

5. The combined refrigeration system according to claim 4, wherein the small air-cooled air conditioner is an air-cooled air conditioner having a modular functionality and is configured to automatically adjust refrigeration capacity and air quantity according to temperature and humidity inside the server cabinet, to achieve linkage control between a plurality of small air-cooled air conditioners.

6. The combined refrigeration system according to claim 1, wherein the outdoor cooling device is one of a dry cooling tower, a wet cooling tower, a plate heat exchanger, a heat pipe exchanger, or another device capable of cooling the liquid.

7. The combined refrigeration system according to claim 1, wherein the liquid cooling unit is either a direct-contact liquid cooling unit or an indirect-contact liquid cooling unit, and is configured to tightly adhere the liquid to a surface or rear face of the CPU/GPU chip, to achieve efficient heat conduction.

8. The combined refrigeration system according to claim 1, wherein the enclosed hot aisle is one of a curtain board made of a soft material, a curtain board made of a hard material, a door, a window, or a structure configured to isolate air flow.
